(19) United States
(12) Patent Application Publication
(10) Pub. No.: US 2026/0143719 A1
(43) Pub. Date: May 21, 2026

(54) SEMICONDUCTOR DEVICE AND METHOD FOR FABRICATING THE SAME

(71) Applicant: SK hynix Inc., Gyeonggi-do (KR)

(72) Inventors: Keo Rock CHOI, Gyeonggi-do (KR); Jeong Myeong KIM, Gyeonggi-do (KR); Cha Deok DONG, Gyeonggi-do (KR)

(21) Appl. No.: 19/239,949

(22) Filed: Jun. 17, 2025

(30) Foreign Application Priority Data
Nov. 19, 2024 (KR) 10-2024-0164786

(51) Int. Cl. H10B 63/00; H10N 70/00

(52) U.S. Cl. CPC H10B 63/22; H10B 63/845; H10N 70/043; H10N 70/826; H10N 70/841; H10N 70/883; H10N 70/8845

(57) ABSTRACT

A semiconductor device and a method for making the semiconductor device, the semiconductor device comprising a plurality of memory cells, each of the memory cells including: a first electrode layer; a memory layer; and a selector layer suitable for selecting the memory layer that is formed in an upper or lower portion of the memory layer and over the first electrode layer, wherein the selector layer includes a dielectric material layer that is doped with a first dopant, and wherein a lower portion region in the dielectric material layer of the selector layer which is adjacent to the first electrode layer has a lower dopant concentration than an upper portion region of the dielectric material layer.

### CROSS-REFERENCE TO RELATED APPLICATIONS

The present application claims priority under 35 U.S.C 119(a) to Korean Patent Application No. 10-2024-0164786, filed on Nov. 19, 2024, which is incorporated herein by reference in its entirety.

### BACKGROUND

### 1. Field

Embodiments of the present disclosure relate generally to semiconductor technology, and more particularly, to a semiconductor device including a memory cell having a selector, and a method for fabricating the semiconductor device.

### 2. Description of the Related Art

Recently, semiconductor devices that are capable of storing data in diverse electronic devices, such as computers and portable communication devices, are demanded to cope with the trends of miniaturization, low power consumption, high performance, and diversification of electronic devices, and researchers and the industry are studying to develop such semiconductor devices. The semiconductor devices include those capable of storing data by taking advantage of the characteristics of switching between different resistance states according to the applied voltage or current, for example, a Resistive Random Access Memory (RRAM), a Phase-change Random Access Memory (PRAM), a Ferroelectric Random Access Memory (FRAM), a Magnetic Random Access Memory (MRAM), an e-fuse and the like.

Moreover, a memory device having a variable resistance element may include a selector as an element for selecting a particular memory cell among a plurality of memory cells that are arrayed, and the selector may be realized as a thin layer in a memory cell.

### SUMMARY

Embodiments of the present disclosure are directed to a semiconductor device capable of preventing damage to the interface between a selector layer and a lower electrode layer when the selector layer of a memory cell is formed, and a method for fabricating the semiconductor device.

In accordance with an embodiment of the present disclosure, a semiconductor device comprises a plurality of memory cells, each of the memory cells including a first electrode layer; a memory layer; and a selector layer suitable for selecting the memory layer that is formed in an upper or lower portion of the memory layer and over the first electrode layer, wherein the selector layer includes a dielectric material layer that is doped with a first dopant, and wherein a lower portion region in the dielectric material layer of the selector layer which is adjacent to the first electrode layer has a lower dopant concentration than an upper portion region of the dielectric material layer.

In accordance with another embodiment of the present disclosure, a method for fabricating a semiconductor device including a selector layer in a memory cell to control an electrical access to one memory cell among a plurality of arrayed memory cells, the method comprising: forming a first electrode layer over a substrate; forming a dielectric material layer for the selector layer over the first electrode layer; and forming the selector layer in which a lower portion region in the dielectric material layer which is adjacent to the first electrode layer has a lower dopant concentration than an upper portion region thereof by performing a plurality of dopant implantation processes using different ion implantation energies into the dielectric material layer.

These and other features and advantages of the present invention will become better understood from descriptions of embodiments in conjunction with the following figures.

### BRIEF DESCRIPTION OF THE DRAWINGS

FIG. 1 is a perspective view illustrating a semiconductor device in accordance with an embodiment of the present disclosure.

FIG. 2 is a cross-sectional view illustrating a structure of a selector unit in detail in accordance with the embodiment of FIG. 1.

FIG. 3 illustrates an operation of the selector unit shown in FIG. 2.

FIGS. 4A to 4D are cross-sectional views illustrating a semiconductor device and a method for fabricating the same in accordance with an embodiment of the present disclosure.

FIGS. 5A to 5D are cross-sectional views illustrating a semiconductor device and a method for fabricating the same in accordance with an embodiment of the present disclosure.

### DETAILED DESCRIPTION

Embodiments of the present disclosure will be described below in more detail with reference to the accompanying drawings. The embodiments may, however, be embodied in different forms and should not be construed as limited to the embodiments set forth herein. Rather, these embodiments are provided so that this disclosure will be thorough and complete, and will fully convey the scope of the present disclosure to those skilled in the art. Throughout this disclosure, like reference numerals refer to like parts throughout the various figures and embodiments of the present disclosure.

Hereinafter, the diverse embodiments of the present disclosure will be described in detail with reference to the attached drawings.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

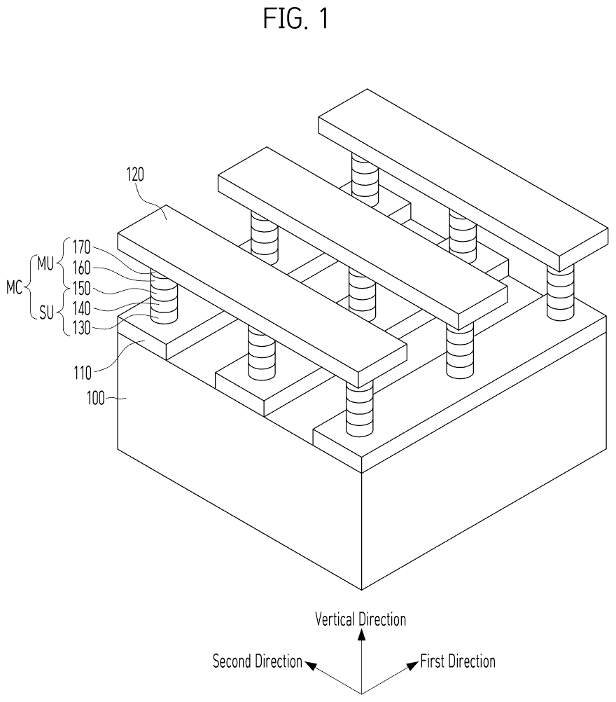

FIG. 1 is a perspective view illustrating a semiconductor device in accordance with an embodiment of the present disclosure.

Referring to FIG. 1, the semiconductor device may include a substrate 100, and a plurality of first interconnections 110 disposed over the substrate 100. Each of the first interconnections 110 is extending in a first direction. In an embodiment, the first interconnections 110 are spaced apart from each other at a regular interval along a second direction. The semiconductor device may also include a plurality of second interconnections 120 spaced apart from each other at a regular interval along a first direction and disposed over the first interconnections 110 and extending in the second direction. The second direction intersects with the first direction. The semiconductor device further includes a plurality of memory cells MC disposed to respectively overlap with the intersection regions between the first interconnections 110 and the second interconnections 120. In an embodiment, the plurality of memory cells MC are disposed between the first interconnections 110 and the second interconnections 120. Here, the first direction and the second direction may refer to directions substantially parallel to the surface of the substrate 100. The direction substantially perpendicular to the surface of the substrate 100 may be, hereinafter, referred to as a vertical direction.

The substrate 100 may include a semiconductor material, such as silicon. Also, a predetermined lower structure (not shown) may be formed in the substrate 100. For example, an integrated circuit for driving the first interconnections 110 and/or the second interconnections 120 may be formed in the substrate 100.

The plurality of the first interconnections 110 may be disposed spaced apart from each other in the second direction. The first interconnections 110 may include a conductive material selected from diverse conductive materials, including, for example, metals such as platinum (Pt), tungsten (W), aluminum (Al), copper (Cu), tantalum (Ta) and the like, metal nitrides such as titanium nitride (TiN), tantalum nitride (TaN) and the like, and combinations thereof. The first interconnections 110 may have a single-layer structure or a multi-layer structure.

The plurality of second interconnections 120 may be disposed spaced apart from each other at a regular interval in the first direction. The second interconnections 120 may include a conductive material selected from diverse conductive materials, including, for example, metals such as platinum (Pt), tungsten (W), aluminum (Al), copper (Cu), tantalum (Ta) and the like, metal nitrides such as titanium nitride (TiN), tantalum nitride (TaN) and the like, and combinations thereof. The second interconnections 120 may have a single-layer structure or a multi-layer structure. One of the first interconnection 110 and the second interconnection 120 may function as a word line, and the other may function as a bit line. Although this embodiment of the present disclosure describes a cross-point structure of one layer, two or more cross-point structures may be stacked in the vertical direction.

Each of the memory cells MC may include a memory unit MU, which is a portion where data are actually stored, and a selector unit SU that controls access to the memory unit MU. For example, the memory cell MC may include a stacked structure of a lower electrode layer 130, a selector layer 140, an intermediate electrode layer 150, a variable resistance layer 160, and an upper electrode layer 170. Here, the selector unit SU may include the lower electrode layer 130, the selector layer 140, and the intermediate electrode layer 150. The memory unit MU may include the intermediate electrode layer 150, the variable resistance layer 160, and the upper electrode layer 170. That is, the intermediate electrode layer 150 may be shared by the selector unit SU and the memory unit MU. Each of the memory cells MC may include a memory layer, which may be a variable resistance layer 160.

The lower electrode layer 130 and the upper electrode layer 170 may be disposed at opposite ends of the memory cell MC, that is, at the bottom end and the top end, respectively, and may function to transfer a voltage or a current that is required for an operation of the memory cell MC. The intermediate electrode layer 150 may electrically connect the selector layer 140 and the variable resistance layer 160 to each other while physically separating them from each other. The lower electrode layer 130, the intermediate electrode layer 150, or the upper electrode layer 170 may include diverse conductive materials, for example, metals such as platinum (Pt), tungsten (W), aluminum (Al), copper (Cu), tantalum (Ta), titanium (Ti) and the like, metal nitrides such as titanium nitride (TiN), tantalum nitride (TaN) and the like, and combinations thereof. Also, the lower electrode layer 130, the intermediate electrode layer 150, or the upper electrode layer 170 may include a carbon electrode. For example, the lower electrode layer 130 and the intermediate electrode layer 150 may include TiN thin layer. A TiN thin layer, as used herein, refers to a layer having a thickness of 5 nm to 100 nm, or more specifically, 5 nm to 50 nm.

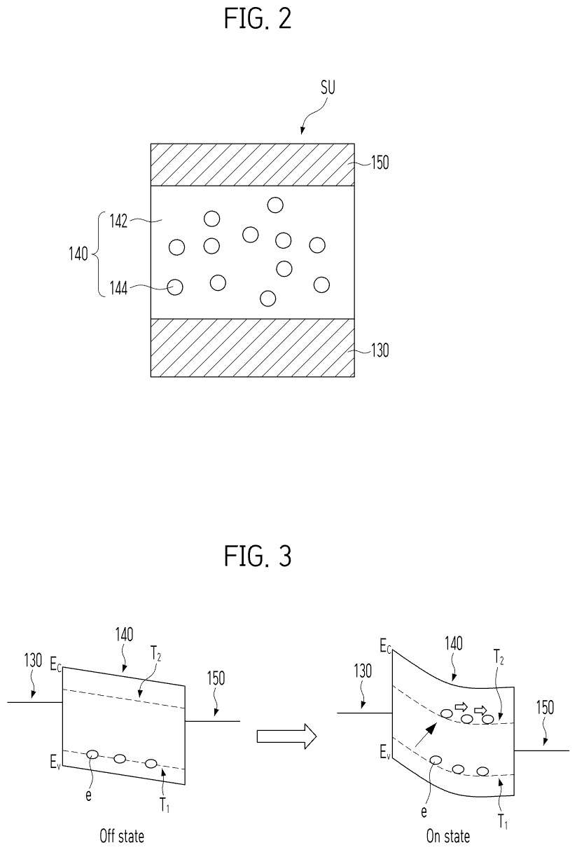

The selector layer 140 may function to prevent current leakage that may occur between the memory cells MC that share the first interconnection 110 or the second interconnection 120 while controlling the access to the variable resistance layer 160. To this end, the selector layer 140 may have the threshold switching characteristics that block current or hold the current to hardly flow when the level of the voltage supplied to the upper and lower ends of the selector layer 140 is lower than a predetermined threshold voltage, and then allows the current to rapidly flow when the level of the voltage supplied to the upper and lower ends of the selector layer 140 is equal to or higher than the threshold voltage. The selector layer 140 may be turned on at the voltage level equal to or higher than the threshold voltage and turned off at the voltage level lower than the threshold voltage. For example, the selector layer 140 may include a dielectric material into which a dopant is implanted. The selector unit SU including the selector layer 140 and the operation of the selector unit SU may be described in detail with reference to FIGS. 2 and 3 below. Each of the memory cells MC may include a carbon (C) thin layer at an interface between the selector layer 140 and the intermediate electrode layer 160. A carbon (C) thin layer, as used herein, refers to a layer having a thickness of 0.5 nm to 20 nm, or more specifically, 0.5 nm to 5 nm.

FIG. 2 is a cross-sectional view illustrating a structure of the selector unit SU in detail in accordance with the embodiment of FIG. 1.

Referring to FIG. 2, the selector unit SU may include the lower electrode layer 130, the selector layer 140, and the intermediate electrode layer 150.

As described above, the lower electrode layer 130 and the intermediate electrode layer 150 may include diverse conductive materials, for example, metals, metal nitrides, and the like. The lower electrode layer 130 and the intermediate electrode layer 150 may be formed of the same material, and thus they may have the same work function. For example, the lower electrode layer 130 and the intermediate electrode layer 150 may include titanium nitride (TiN) having a work function of approximately 4.4 to 4.6 eV. As used herein, the term ‘approximately’ when referring to a numerical range means within ±5% of the stated value. However, the concept and scope of the present disclosure are not limited thereto, and the lower electrode layer 130 and the intermediate electrode layer 150 may be formed of different materials to have different work functions.

The selector layer 140 may include a dielectric material layer 142 and a dopant 144 which is implanted into the dielectric material layer 142.

The dielectric material layer 142 may include a dielectric material having a relatively wide band gap, for example, a dielectric material having a band gap of approximately 5.0 eV or more. For example, the dielectric material layer 142 may include a silicon-containing dielectric material such as silicon oxide, silicon nitride, silicon oxynitride and the like, a dielectric metal oxide, a dielectric metal nitride, or a combination thereof. For example, an oxide layer such as silicon dioxide (SiO₂) may be formed by mixing a source gas including silicon (Si) and oxygen (O) through a process, such as a Chemical Vapor Deposition (CVD) process, a Physical Vapor Deposition (PVD) process, or an Atomic Layer Deposition (ALD) process. The dielectric material layer 142 may have a deep trap whose energy level is closer to the energy level of the valence band than to the energy level of the conduction band of the dielectric material layer 142. The dopant 144 may serve to create a shallow trap that provides a passage for conductive carriers, such as electrons or holes, to move in the dielectric material layer 142. The shallow trap may have an energy level which is closer to the energy level of the conduction band than to the energy level of the valence band of the dielectric material layer 142. The dopant doped into the selector layer 140 may include an n-type or p-type dopant, and the dopant may be implanted by an ion implantation process. For example, when the dielectric material layer 142 contains silicon, the dopant 144 may include a metal having a different valence from the valence of silicon, such as gallium (Ga), boron (B), indium (In), phosphorus (P), arsenic (As), antimony (Sb), germanium (Ge), carbon (C), tungsten (W), and a combination thereof. Also, when the dielectric material layer 142 contains a metal, the dopant 144 may include a metal having a different valence from the valence of the metal, such as silicon. For example, the dielectric material layer 142 may include silicon oxide, such as silicon dioxide (SiO₂), and the dopant 144 may include arsenic (As). The selector layer 140 may include silicon dioxide (SiO₂) doped with arsenic (As).

The operation of the selector unit SU may be described below with reference to FIG. 3.

FIG. 3 illustrates an operation of the selector unit SU shown in FIG. 2.

Referring to FIG. 3, in the off-state where no voltage is applied to the selector unit SU, conductive carriers, for example, electrons “e”, may be trapped in the deep trap T₁ of the selector layer 140.

When a voltage equal to or higher than the threshold voltage is applied to the selector unit SU of the off-state through the lower electrode layer 130 and the upper electrode layer 150, an on-state in which current flows through the selector unit SU may be realized. To be specific, when a voltage equal to or higher than the threshold voltage is applied to the selector unit SU, the conductive carriers trapped in the deep trap T₁ may jump to the shallow trap T₂ through a thermal emission process or a tunneling process, and the conductive carriers may move through the shallow trap T₂ to create a conductive path coupling the lower electrode layer 130 and the upper electrode layer 150.

When the voltage applied to the selector unit SU of the on-state decreases, the number of the conductive carriers moving from the deep trap T₁ to the shallow trap T₂ may also decrease, so that the selector unit SU may go back to the off-state.

In this way, the selector unit SU may be turned on and off.

Referring back to FIG. 1, the variable resistance layer 160 may be a portion that stores data in the memory cell MC. To this end, the variable resistance layer 160 may have the variable resistance characteristics of switching between different resistance states according to the applied voltage. The variable resistance layer 160 may have a single-layer structure or a multi-layer structure including diverse materials used in a Resistive Random Access Memory (RRAM), a Phase-change Random Access Memory (PRAM), a Ferroelectric Random Access Memory (FRAM), a Magnetic Random Access Memory (MRAM) and the like, for example, metal oxides such as transition metal oxides, perovskite-based materials and the like, phase change materials such as chalcogenide-based materials, ferroelectric materials, ferromagnetic materials, and the like. For example, the variable resistance layer 160 may include a magnetic tunnel junction structure that may store data by switching between different resistance states by changing the magnetization direction.

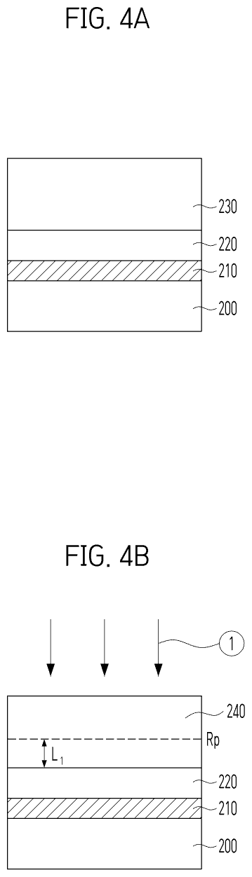

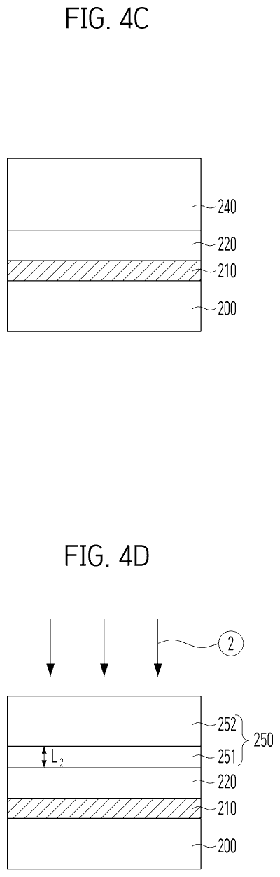

FIGS. 4A to 4D are cross-sectional views illustrating a semiconductor device and a method for fabricating the same in accordance with an embodiment of the present disclosure.

First, the method for fabricating the semiconductor device will be described.

Referring to FIG. 4A, a substrate 200 having a predetermined lower structure may be provided. The substrate 200 may include required diverse circuits. The substrate 200 may include interconnections which are similar to the first interconnections 110 of FIG. 1.

Subsequently, a lower electrode layer 210, a barrier layer 220, and a dielectric material layer 230 may be formed over the substrate 200. The lower electrode layer 210, the barrier layer 220, and the dielectric material layer 230 may be formed sequentially in the recited order over the substrate 200. The lower electrode layer 210 may be formed on the substrate 200 by depositing a conductive material on the substrate 200. Then, the barrier layer 220 may be formed on the lower electrode layer 210. The barrier layer 220 may be disposed between the lower electrode layer 210 and the dielectric material layer 230. The barrier layer 220 may prevent damage to the lower electrode layer 210 that may occur during an ion implantation process, which is described below. The barrier layer 220 may include silicon nitride, carbon, or a transition metal oxide. The barrier layer 220 may be deposited over the lower electrode layer 210 by a Physical Vapor Deposition (PVD) process, a Chemical Vapor Deposition (CVD) process, or an Atomic Layer Deposition (ALD) process. Also, the barrier layer 220 may be formed directly on the surface of the lower electrode layer 210 through a thermal oxidation process, or may be formed by applying an oxidizing agent to the surface of the lower electrode layer 210 to form an oxide layer. The dielectric material layer 230 may be formed by mixing source gases through a process such as a Physical Vapor Deposition (PVD) process, a Chemical Vapor Deposition (CVD) process, or an Atomic Layer Deposition (ALD) process. The dielectric material layer 230 may have a thickness of approximately 50 to 150 Å.

Referring to FIG. 4B, an initial selector layer 240 may be formed by depositing the dielectric material layer 230 onto the barrier layer 220 and then implanting a dopant into the dielectric material layer 230. The implantation of the dopant may be performed, for example, by an ion implantation process, and may be performed toward the dielectric material layer 230 in a direction substantially perpendicular to the surface of the substrate 200 as indicated by the arrows \textcircled{1} in FIG. 4B. The dopant implantation process may be, hereinafter, referred to as a first dopant implantation process.

The dopant implanted herein may be at least one selected from the group including nitrogen (N), phosphorus (P), arsenic (As), antimony (Sb) and the like. In an embodiment, the dopant may be arsenic (As). The implanted dopant may act as a significant factor that determines the electrical characteristics of the selector layer. The first dopant implantation process may be a low-energy ion implantation process, in which the ion implantation energy is set to a specific range so that the ion implantation depth Rp is formed at a point of approximately 30% to 50% of the entire thickness of the dielectric material layer from the lower surface of the dielectric material layer. The height L₁ of the ion implantation depth Rp may correspond to a point of approximately 0.3 to 0.5 of the entire dielectric material layer 230 from the lower surface of the dielectric material layer 230. In an embodiment, the implantation energy may be set in a range of approximately 3 KeV to 7 KeV. W hen the implantation range is controlled within this range, it allows the dopant to be appropriately diffused inside the dielectric material layer 230, and to minimize any damage to the lower electrode layer 210 and the barrier layer 220 while at the same time uniformly forming the selector layer.

The first dopant implantation process may continue until the dopant is implanted into the entire dielectric material layer 230 and scattering of the dopant that occurs here may be limitedly diffused into the lower portion of the ion implantation depth Rp. The subsequent dose may be mostly concentrated on the upper portion of the ion implantation depth Rp. The dopant may be implanted into the dielectric material layer 230 through the first dopant implantation process to form the initial selector layer 240.

Referring to FIG. 4C, the dopant may be additionally implanted toward the initial selector layer 240 into which the dopant has been implanted. This dopant implantation process may be referred to as a second dopant implantation process.

The dopant implanted during the second dopant implantation process may be the same as the dopant of the first dopant implantation process described above. For example, when arsenic (As) is implanted during the first dopant implantation process, arsenic (As) may also be implanted during the second dopant implantation process.

Also, the second dopant implantation process may be performed, for example, by an ion implantation process, and may be performed toward the initial selector layer 240 in a direction substantially perpendicular to the surface of the substrate 200 or the surface of the initial selector layer 240 as indicated by the arrows \textcircled{2} of FIG. 4D. The second dopant implantation process may be performed by using an ion implantation energy that is lower than the ion implantation energy of the first dopant implantation process. The ion implantation energy during the second dopant implantation process may be set to approximately 3 KeV or lower. Through this, it is possible to prevent the disadvantage of the dopant from being implanted into the portions other than the initial selector layer 240, for example, the lower electrode layer 210 or the barrier layer 220 and damaging them, and thus effectively prevent the disadvantage of the performance of the device from being deteriorated due to the damage of these layers. Also, this may allow the dopant to be formed at a high concentration in the final selector layer 250. Also, the dose in the second dopant implantation process may be set to be lower than the dose in the first dopant implantation process. Accordingly, when the dopant is sufficiently implanted into the entire initial selector layer 240 through the first dopant implantation process, the scattering effect due to the second dopant implantation process may act in the direction of reducing the thickness of the initial selector layer 240. This process may allow the thickness of the final selector layer (see 250 in FIG. 4D) to be controlled more precisely and may improve the distribution of the thickness.

Referring to FIG. 4D, the final selector layer 250 having a low-concentration dopant layer with a low dopant concentration in the lower portion and a high-concentration dopant layer with a high dopant concentration in the upper portion may be formed through the second dopant implantation process. The final selector layer 250 may have a profile in which the concentration of the dopant increases as it goes from bottom to top. A lower layer 251 with a relatively low dopant concentration may exist in a lower region of the final selector layer 250, and an upper layer 252 with a relatively high dopant concentration may exist in an upper region of the final selector layer 250. The thickness L₂ of the lower layer 251 may be approximately 80 to 60% of the total thickness of the final selector layer 250, and the thickness of the upper layer 252 may be approximately 20 to 40% of the total thickness of the final selector layer 250. The final selector layer 250 may have a reduced thickness compared to the dielectric material layer 230 through the second ion implantation process. The final selector layer 250 may have a thickness of, for example, approximately 30 to 120 Å.

The semiconductor device in accordance with an embodiment of the present disclosure may be fabricated by the process described above.

Referring back to FIG. 4D, the semiconductor device in accordance with an embodiment of the present disclosure may include the substrate 200, the lower electrode layer 210 formed over the substrate 200, the barrier layer 220 formed over the lower electrode layer 210, and the final selector layer 250 formed over the barrier layer 220.

The thickness L₂ of the lower layer 251 may be approximately 80 to 60% of the total thickness of the final selector layer 250, and the thickness of the upper layer 252 may be approximately 20 to 40% of the total thickness of the final selector layer 250.

According to the described embodiment of the present disclosure and the fabrication method thereof, since the lower layer 251 has a relatively low dopant concentration in the lower portion of the final selector layer 250 it may substantially function not as the selector layer but as the barrier layer 220. Also, the barrier layer 220 and the lower electrode layer 210 formed in the lower portion of the barrier layer 220 may be protected from being damaged due to the two-step dopant implantation process. Accordingly, leakage current may be blocked in the off-state. Also, it is possible not only to form a dopant at a high concentration in the final selector layer 250, but also to more precisely control the thickness of the final selector layer 250 and improve the distribution of the thickness.

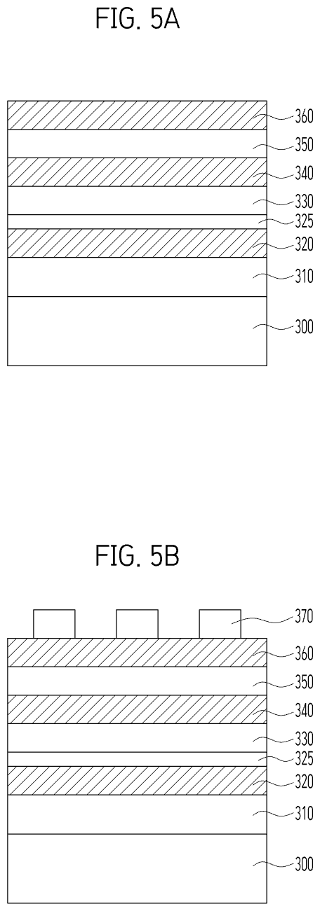

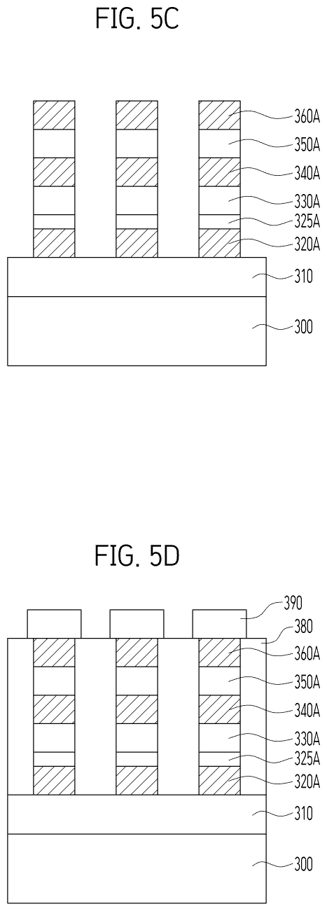

FIGS. 5A to 5D are cross-sectional views illustrating a semiconductor device and a method for fabricating the same in accordance with an embodiment of the present disclosure.

Referring to FIGS. 5A to 5D, the semiconductor device in accordance with the embodiment of the present disclosure may include memory cells MC that are formed between first interconnections 310 extending in the first direction and second interconnections 390 extending in the second direction to overlap with the intersection regions between the first interconnections 310 and the second interconnections 390.

Referring to FIG. 5A, the memory cell MC may include a stacked structure of a lower electrode layer 320, a barrier layer 325, an intermediate electrode layer 340, a variable resistance layer 350, and an upper electrode layer 360, together with a selector layer 330 that is formed by a two-step low-energy ion implantation process over the substrate 300 and the first interconnections 310. The selector layer 330 may have a profile in which the concentration of the dopant increases from bottom to top. The selector layer 330 may have a lower dopant concentration in the lower portion than in the upper portion. While the selector layer 330 is formed, the lower electrode layer 320 and the barrier layer 325 may be protected from being damaged, thus effectively preventing performance deterioration of the device.

The structure formed according to FIGS. 5A to 5D may be substantially the same as the structure of FIG. 1. The first interconnections 310, the lower electrode layer 320, the selector layer 330, the intermediate electrode layer 340, the variable resistance layer 350, and the upper electrode layer 360 may correspond to the first interconnections 110, the lower electrode layer 130, the selector layer 140, the intermediate electrode layer 150, the variable resistance layer 160, and the upper electrode layer 170 of FIG. 1, respectively. Therefore, detailed description of the structure corresponding to the structure of the aforementioned FIG. 1 may be omitted.

Referring to FIG. 5B, a hard mask layer 370 may be formed over the upper electrode layer 360. The hard mask layer 370 may be formed by forming a material layer for the hard mask layer 370 and a photoresist pattern (not shown) and etching the material layer for the hard mask layer 370 with the photoresist pattern being used as an etching barrier. The hard mask layer 370 may provide an etching barrier when the memory cells MC are etched. The hard mask layer 370 may include diverse materials capable of securing an etching selectivity with respect to the memory cells MC. For example, the material layer for the hard mask layer 370 may have a single-layer structure or a multi-layer structure including diverse dielectric materials, such as silicon oxide, silicon nitride, silicon oxynitride and the like.

Referring to FIG. 5C, by sequentially etching the upper electrode layer 360, the variable resistance layer 350, the intermediate electrode layer 340, the selector layer 330, the barrier layer 325, and the lower electrode layer 320 with the hard mask layer 370 being used as an etching barrier, a memory cell MC including an upper electrode pattern 360A, a variable resistance pattern 350A, an intermediate electrode pattern 340A, a selector pattern 330A, a barrier pattern 325A, and a lower electrode pattern 320A may be formed. A sidewall of the variable resistance pattern 350A and a sidewall of the selector pattern 330A may be aligned with each other.

According to the described embodiment of the present disclosure, the hard mask layer 370 may be removed during the memory cell MC etching process. However, according to another embodiment of the present disclosure, part or all of the hard mask layer 370 may remain and may be removed in a planarization process, which is described below.

Referring to FIG. 5D, an inter-layer dielectric layer 380 may be formed over the memory cells MC. The inter-layer dielectric layer 380 may have a thickness that sufficiently fills the space between the memory cells MC and covers the upper portions of the memory cells MC. The inter-layer dielectric layer 380 may have a single-layer structure or a multi-layer structure and may include diverse dielectric materials, such as silicon oxide, silicon nitride, or a combination thereof.

Subsequently, a planarization process, such as a Chemical Mechanical Polishing (CMP) process, may be performed onto the inter-layer dielectric layer 380 until the upper surfaces of the memory cells MC are exposed. Even though the hard mask layer 370 is not completely removed but remains in the aforementioned memory cell MC etching process, the hard mask layer 370 may also be removed because the planarization process is performed until the upper surfaces of the memory cells MC are exposed in this process.

Subsequently, a plurality of second interconnections 390 extending in the second direction intersecting with the first direction, for example, the second direction shown in FIG. 1, may be formed over the memory cell MC and the inter-layer dielectric layer 380 while being coupled to the upper surfaces of the memory cells MC. The second interconnections 390 may be formed by depositing a conductive material and patterning the conductive material. The space between the second interconnections 390 may be filled with a dielectric material (not shown).

By the process described above, the semiconductor device in accordance with the embodiment of the present disclosure as illustrated in FIG. 5D may be fabricated. Even according to this embodiment of the present disclosure, all advantages described in the above-described embodiments of the present disclosure may be obtained.

According to the embodiments of the present disclosure, the semiconductor device and the fabrication method thereof prevent damage to the interface between the selector layer and the lower electrode layer, thereby blocking leakage current in the off-state, and at the same time, increasing the concentration of the dopant that is ion-implanted into the selector layer, and improving the distribution of the thickness of the selector layer.

While the present invention has been described with respect to specific embodiments of the present disclosure, it will be apparent to those skilled in the art that various changes and modifications may be made to the embodiments without departing from the technical concepts and scope of the present disclosure as defined in the following claims. Furthermore, the embodiments may be combined to form additional embodiments.

What is claimed is:

1. A semiconductor device comprising:
a plurality of memory cells, each of the memory cells including:
a first electrode layer;
a memory layer; and
a selector layer suitable for selecting the memory layer that is formed in an upper or lower portion of the memory layer and over the first electrode layer,
wherein the selector layer includes a dielectric material layer that is doped with a first dopant, and
wherein a lower portion region in the dielectric material layer of the selector layer which is adjacent to the first electrode layer has a lower dopant concentration than an upper portion region of the dielectric material layer.

2. The semiconductor device of claim 1, wherein the upper portion region in the dielectric material layer of the selector layer has a thickness of approximately 80 to 60% of a total thickness of the selector layer, and
the lower region in the dielectric material layer of the selector layer has a thickness of approximately 20 to 40% of the total thickness of the selector layer.

3. The semiconductor device of claim 1, wherein the selector layer has a thickness of approximately 30 to 120 Å.

4. The semiconductor device of claim 1, wherein the memory cell further includes a barrier layer disposed below the selector layer, and
wherein the barrier layer includes silicon nitride, carbon or a transition metal oxide.

5. The semiconductor device of claim 4, wherein the memory cell further includes,
a first electrode layer disposed below the barrier layer, and
a second electrode layer disposed over the selector layer.

6. The semiconductor device of claim 5, wherein the first electrode layer and the second electrode layer include a TiN layer.

7. The semiconductor device of claim 5, further comprising:
a carbon (C) layer at an interface between the selector layer and the second electrode layer.

8. The semiconductor device of claim 1, wherein a sidewall of the memory layer and a sidewall of the selector layer are aligned with each other.

9. The semiconductor device of claim 1, wherein the first dopant includes gallium (Ga), boron (B), indium (In), phosphorus (P), arsenic (As), antimony (Sb), germanium (Ge), carbon (C), tungsten (W), or a combination thereof.

10. The semiconductor device of claim 1, wherein the first dopant includes arsenic (As).

11. The semiconductor device of claim 1, wherein the memory layer is a variable resistance layer.

12. A method for fabricating a semiconductor device including a selector layer in a memory cell to control an electrical access to one memory cell among a plurality of arrayed memory cells, the method comprising:
forming a first electrode layer over a substrate;
forming a dielectric material layer for the selector layer over the first electrode layer; and
forming the selector layer in which a lower portion region in the dielectric material layer which is adjacent to the first electrode layer has a lower dopant concentration than an upper portion region thereof by performing a plurality of dopant implantation processes using different ion implantation energies into the dielectric material layer.

13. The method of claim 12, wherein the dopant implantation process is performed twice, and
wherein the first dopant implantation process is performed with an ion implantation energy such that an ion implantation depth (Rp) is formed at a height point of approximately 30% to 50% of a total thickness of the dielectric material layer from a lower surface of the dielectric material layer, and
wherein the second dopant implantation process is performed with an ion implantation energy which is lower than the ion implantation energy of the first dopant implantation process.

14. The method of claim 13, wherein the ion implantation energy of the first dopant implantation process ranges from approximately 3 KeV to 7 KeV.

15. The method of claim 12, wherein the lower portion region in the dielectric material layer has a thickness of approximately 80 to 60% of the total thickness of the selector layer, and
wherein the upper portion region in the dielectric material layer has a thickness of approximately 20 to 40% of the total thickness of the selector layer.

16. The method of claim 13, wherein the first dopant implantation process is performed until the first dopant is implanted into the entire dielectric material layer.

17. The method of claim 12, further comprising
forming a barrier layer between the first electrode layer and the selector layer.

18. The method of claim 17, wherein the barrier layer is formed by a Physical Vapor Deposition (PVD) process, a Chemical Vapor Deposition (CVD) process, or an Atomic Layer Deposition (ALD) process.

19. The method of claim 17, wherein the barrier layer includes silicon nitride, carbon, or a transition metal oxide.

20. The method of claim 12, wherein the dopant ion-implanted into the dielectric material layer includes gallium (Ga), boron (B), indium (In), phosphorus (P), arsenic (As), antimony (Sb), germanium (Ge), carbon (C), tungsten (W), or a combination thereof.
